(19) United States
(12) Patent Application Publication
(10) Pub. No.: US 2026/0190978 A1
(43) Pub. Date: Jul. 2, 2026

(54) DISPLAY DEVICE

(71) Applicant: LG Display Co., Ltd., Seoul (KR)

(72) Inventors: Dongkyu Lee, Goyang-si (KR); Jungho Bang, Paju-si (KR); Kyu-Hwang Lee, Paju-si (KR); Munchan Kang, Goyang-si (KR)

(73) Assignee: LG Display Co., Ltd., Seoul (KR)

(21) Appl. No.: 19/414,927

(22) Filed: Dec. 10, 2025

(30) Foreign Application Priority Data
Dec. 31, 2024 (KR) 10-2024-0202050

(51) Int. Cl. H10W 20/43; G02F 1/1362; H10D 86/40; H10D 86/60

(52) U.S. Cl. CPC H10W 20/43; H10D 86/443; H10D 86/60; G02F 1/136286

(57) ABSTRACT

Disclosed is a display device including a first substrate including a display area and a non-display area surrounding the display area, a second substrate facing the first substrate, a plurality of link lines disposed in the non-display area of the first substrate, the plurality of link lines being disposed at different distances from the second substrate, a plurality of protective structures respectively on link lines closest to the second substrate, among the plurality of link lines, a plurality of shock-absorbing structures between the second substrate and the plurality of protective structures, respectively, and a sealing material surrounding the plurality of shock-absorbing structures in the non-display area between the first substrate and the second substrate.

### CROSS REFERENCE TO RELATED APPLICATION

The present application claims priority to Korean Patent Application No. 10-2024-0202050, filed Dec. 31, 2024, the entire contents of which is incorporated herein for all purposes by this reference.

### BACKGROUND

### Field

The present disclosure relates to a display device.

### Description of Related Art

A display device is applied to various electronic devices, such as a TV, a smartphone, a laptop computer, and a tablet. To this end, research is continuing for thinness, lighter weight, low power consumption, and the like for display devices.

Examples of the display devices may include, among others, a liquid crystal display (LCD) device, a field emission display (FED) device, and an organic light emitting display (OLED) device.

The liquid crystal display device is a display device that displays an image by adjusting an amount of light that transmits through a liquid crystal. It has advantages of being thinner and lighter and having lower power consumption than other earlier display devices, and thus has been widely used.

### SUMMARY

In a liquid crystal display device, an upper substrate and a lower substrate of the display device are bonded together using a sealing material applied to a bezel area, which is a non-display area disposed outward of a display area. The bezel area may include a link area. In the link area, link lines for providing various signals from an external source to a plurality of signal lines disposed in the display area may be disposed.

Recently, as a resolution of the liquid crystal display increases, a larger number of link lines are employed. In addition, as a width of the bezel area is reduced, a demand for a display device for satisfying user's aesthetic sense is also increasing. In a process of applying designs and technologies for reducing the width of the bezel area while disposing a larger number of link lines on the bezel area, cracks may occur in the link lines by stress. When moisture penetrates into the link lines in which the cracks have occurred, corrosion may occur in the lines. When the lines are corroded and damaged, a defect may occur in an operation of the display device, so that reliability of a product may be deteriorated.

Accordingly, through various experiments, the inventors of the present disclosure have invented a display device capable of preventing or suppressing potential cracks in or damage to link lines disposed on a bezel area caused by stress from occurring.

A purpose of one or more embodiments of the present disclosure is to provide a display device capable of preventing or suppressing cracks from occurring in link lines due to stress, thereby preventing or suppressing damages to the link lines.

Another purpose of one or more embodiments of the present disclosure is to provide a display device capable of placing multiple link lines in a limited bezel area by applying a structure in which multiple link lines are arranged at different layers.

Yet another purpose of one or more embodiment of the present disclosure is to provide a display device including a robust structure to protect link lines from being damaged when an upper substrate and a lower substrate are bonded to each other.

Purposes according to various embodiments of the present disclosure are not limited to the above-mentioned purposes. Other purposes and advantages according to the present disclosure that are not mentioned may be understood based on following descriptions and may be more clearly understood based on example embodiments of the present disclosure. Further, it can be easily understood from the descriptions provided herein that the purposes and advantages according to various example embodiments of the present disclosure may be realized by practicing the example embodiments described herein, including in the claims or combinations thereof.

To achieve these objects and other advantages and in accordance with purposes of the present disclosure, as embodied and broadly described herein, a display device according to an embodiment of the present disclosure includes a first substrate including a display area and a non-display area surrounding the display area, a second substrate facing the first substrate, a plurality of link lines disposed in the non-display area of the first substrate, the plurality of link lines being disposed at different distances from the second substrate, a plurality of protective structures respectively on link lines closest to the second substrate, among the plurality of link lines, a plurality of shock-absorbing structures between the second substrate and the plurality of protective structures, respectively, and a sealing material surrounding the plurality of shock-absorbing structures in the non-display area between the first substrate and the second substrate.

In another aspect of the present disclosure, a display device includes a first substrate including a display area and a non-display area surrounding the display area, a second substrate overlapping the first substrate, a plurality of link lines in the non-display area of the first substrate, the plurality of link lines being disposed respectively at different distances from the second substrate, a protective structure on a link line closest to the second substrate among the plurality of link lines, and at least one shock-absorbing structure between the protective structure and the second substrate.

According to an example embodiment of the present disclosure, by placing the protective structures on the link lines disposed on the bezel area, the link lines may be prevented from being cracked or damaged by the stress. Accordingly, external moisture or the like may be prevented from corroding the lines via the cracks.

According to an example embodiment of the present disclosure, by placing the gap filler or the auxiliary structure, which is the shock-absorbing structure, on the protective structure, the robust structure capable of alleviating the stress applied to the line when the upper substrate and the lower substrate are bonded to each other may be constructed.

According to an example embodiment of the present disclosure, the multiple link lines may be disposed in the limited bezel area by applying the triple link line structure in which the multiple link lines are disposed at the different layers. Accordingly, the resolution of the liquid crystal display may be increased.

According to example embodiments of the present disclosure, because the defect rate of the display device resulted from the corrosion of the link lines is reduced, the production energy required for the additional production of the display device may be reduced, thereby reducing the emission of the greenhouse gas.

Effects of the present disclosure are not limited to the effects mentioned above, and other effects not mentioned may be clearly understood by those skilled in the art from the description as set forth below.

In addition to the above effects, specific effects of the present disclosure are described together in, or may be understood from, the description of specific details for implementing the example embodiments of the present disclosure detailed below.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain the principles of the disclosure.

FIG. 1 is a plan view of a display device according to an example embodiment of the present disclosure.

FIGS. 2 to 4 are diagrams illustrating a display device according to an example embodiment of the present disclosure.

FIG. 5 is a plan view illustrating a portion of a link area according to another example embodiment of the present disclosure.

FIGS. 6 to 9 are diagrams illustrating a method for manufacturing a display device according to another example embodiment of the present disclosure.

FIGS. 10 and 11 are diagrams illustrating a display device according to still another example embodiment of the present disclosure.

### DETAILED DESCRIPTION

Advantages and features of the present disclosure, and a method of achieving the advantages and features will become apparent with reference to example embodiments described below in detail together with the accompanying drawings. However, the present disclosure is not limited to the example embodiments as disclosed below but may be implemented in various other forms. Thus, these embodiments are set forth only to make the present disclosure more complete, and to more fully inform the scope of the present disclosure to those of ordinary skill in the technical field to which the present disclosure belongs. The protected scope of the present disclosure may be defined by the scope of the claims and their equivalents.

For simplicity and clarity of illustration, elements in the drawings are not necessarily drawn to scale. The same reference numbers in different drawings represent the same or similar elements, and as such perform similar functionality, unless otherwise specified. Further, descriptions and details of well-known steps and elements may be omitted for simplicity of the description. Furthermore, in the following detailed description of example embodiments of the present disclosure, numerous specific details may be set forth to provide a thorough understanding of the present disclosure. However, it should be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It should be understood that the description herein is not intended to limit the claims to the specific embodiments described. On the contrary, it is intended to cover alternatives, modifications, and equivalents as may be included within the spirit and scope of the present disclosure as defined by the appended claims and their equivalents.

A shape, a size, a ratio, an angle, a number, etc., disclosed in the drawings for illustrating example embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It should be further understood that the terms “comprise,” “comprising,” “include,” and “including,” where used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expressions like “at least one of,” where preceding a list of elements, may modify the entire list of elements and may not modify the individual elements of the list. In interpretation of numerical values, an error or tolerance therein may occur even where there is no explicit description thereof.

In addition, it should also be understood that when a first element or layer is referred to as being present “on” a second element or layer, the first element may be disposed directly on the second element or may be disposed indirectly on the second element with a third element or layer being disposed between the first and second elements or layers. It should be understood that, where an element or layer is referred to as being “connected to” or “coupled to” another element or layer, it may be directly connected to or coupled to the other element or layer, or one or more intervening elements or layers may be present therebetween. In addition, it should also be understood that, where an element or layer is referred to as being “between” two elements or layers, it may be the only element or layer between the two elements or layers, or one or more intervening elements or layers may also be present.

Further, as used herein, where a layer, film, area, plate, or the like is described as being disposed “on” or “on top” of another layer, film, area, plate, or the like, the former may directly contact the latter or still another layer, film, area, plate, or the like may be disposed between the former and the latter. As used herein, where a layer, film, area, plate, or the like is described as being directly disposed “on” or “on top” of another layer, film, area, plate, or the like, the former directly contacts the latter, and still another layer, film, area, plate, or the like is not disposed between the former and the latter. Further, as used herein, where a layer, film, area, plate, or the like is described as being disposed “beneath” or “under” another layer, film, area, plate, or the like, the former may directly contact the latter or still another layer, film, area, plate, or the like may be disposed between the former and the latter. As used herein, where a layer, film, area, plate, or the like is described as being directly disposed “beneath” or “under” another layer, film, area, plate, or the like, the former directly contacts the latter, and still another layer, film, area, plate, or the like is not disposed between the former and the latter.

In descriptions of temporal relationships, for example, temporal precedent relationships between two events such as “after,” “subsequent to,” “before,” etc., another event may occur therebetween unless a more limiting phrase like “directly after,” “directly subsequent,” or “directly before” is not indicated.

Where a certain embodiment may be implemented differently, a function or an operation specified in a specific block may occur in a different order from an order specified in a flowchart. For example, two blocks in succession may be actually performed substantially concurrently, or the two blocks may be performed in a reverse order, depending on a function or operation involved.

It should be understood that, although the terms “first,” “second,” “third,” and so on may be used herein to describe various elements, components, areas, layers, and/or periods, these elements, components, areas, layers, and/or periods should not be interpreted as being limited by these terms. These terms are used to refer to one element, component, area, layer, or period separately from another element, component, area, layer, or period. Thus, a first element, component, area, layer, or period as described herein could be termed a second element, component, area, layer, or period, and vice versa, without departing from the spirit and scope of the present disclosure.

The features of the various embodiments of the present disclosure may be partially or entirely combined with each other and may be technically associated with each other or operate with each other. The embodiments may be implemented independently of each other or may be implemented together in an association relationship.

In interpreting a numerical value, the value is to be interpreted as including an error range unless otherwise specified.

Unless otherwise defined, all terms including technical and scientific terms used herein have the same meaning as commonly understood by one of ordinary skill in the art to which this disclosure belongs. It should be further understood that terms, such as those defined in commonly used dictionaries, should be interpreted as having a meaning that is consistent with their meaning in the context of the relevant art and should not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term “or” means “inclusive or” rather than “exclusive or.” That is, unless otherwise stated or clear from the context, the expression that “x uses a or b” means one of natural inclusive permutations.

The terms used in the description below have been selected as being general and universal in the related technical field. However, there may be other terms that are equivalent, similar, or appropriate depending on the development and/or change of technology, convention, preference of technicians, etc. Therefore, the terms used in the description below should not be understood as limiting technical ideas but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Description.

In description of flow of a signal, for example, where a signal is described as being delivered from a node A to a node B, this may include a case where the signal is transferred from the node A to the node B via another node unless a more limiting phrase like “immediately transferred” or “directly transferred” is used.

Throughout the present disclosure, if used, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components encompasses not only a first, second, or third component individually, but also all combinations of two or more of the first, second, and third components.

Hereinafter, example embodiments of the present disclosure will be described with reference to the attached drawings. A scale of each of components as shown in the drawings may be different from an actual scale thereof for convenience of illustration. Therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

Hereinafter, a display device according to example embodiments of the present disclosure will be described with reference to the drawings.

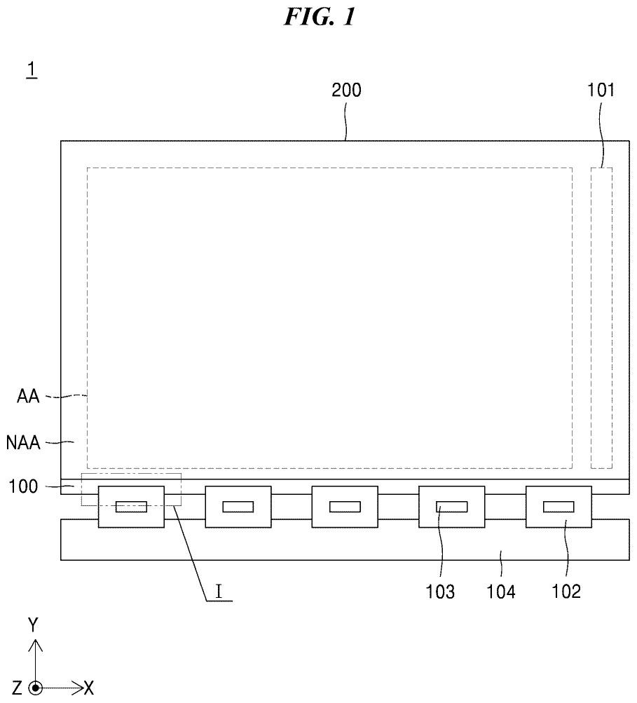

FIG. 1 is a plan view of a display device according to an example embodiment of the present disclosure.

As illustrated in FIG. 1, a display device 1 according to an example embodiment of the present disclosure may include a display panel including a display area AA and a non-display area NAA located outward of the display area AA. The display panel according to an example embodiment of the present disclosure may include a first substrate 100 and a second substrate 200 overlapping the first substrate 100. A pixel driving circuit including a plurality of thin film transistors (TFTs) may be disposed on the first substrate 100, and a color filter layer corresponding to a plurality of pixels may be disposed on the second substrate 200.

The display area AA may be an area in which an image is displayed. The non-display area NAA may be an area in which no image is displayed. The non-display area NAA may be located in a peripheral area (or an edge area) of the first substrate 100 but may not be limited thereto. For example, an area other than a light-emissive area in which light is emitted to the outside on the display area AA may be referred to as the non-display area NAA. The non-display area NAA located in the peripheral area (or the edge area) of the first substrate 100 may be referred to as a bezel area.

The plurality of pixels may be disposed in the display area AA, and the image may be displayed in the display area AA accordingly. Various lines, circuits, and the like for driving the plurality of pixels of the display area AA may be disposed in the non-display area NAA. For example, driving circuits, including a gate driving circuit and a data driving circuit, may be disposed in the non-display area NAA. Several drivers 101 for driving the display area AA may be disposed in the non-display area NAA. For example, the driver 101 may include a gate driver and a data driver, but may not be limited thereto.

A flexible circuit board 102 and a printed circuit board 104 may be disposed at an edge of at least one side of the non-display area NAA. For example, a plurality of flexible circuit boards 102 may be disposed, but the present disclosure may not be limited thereto. An integrated circuit chip 103 may be disposed on the flexible circuit board 102. One side of the flexible circuit board 102 may be coupled to the first substrate 100, and the other side thereof may be coupled to the printed circuit board 104 to provide power and signals for driving the pixels supplied from the printed circuit board 104 to the display area AA of the first substrate 100. For example, the signals for driving the pixels may include a high potential voltage, a low potential voltage, a scan signal, a data signal, or the like.

The printed circuit board 104 may supply various signals to the integrated circuit chip 103 disposed on the flexible circuit board 102. Various components for supplying the various signals to the integrated circuit chip 103 may be disposed on the printed circuit board 104.

The first substrate 100 and the second substrate 200 may be bonded to each other using a sealing material. The sealing material may be disposed in a manner of being applied along the non-display area NAA at an edge of the first substrate 100 or an edge of the second substrate 200.

Because the pixels are not disposed in an area in which the sealing material is disposed, the corresponding area may be blocked by a black matrix so as not to be visible from the outside. The non-display area NAA blocked by the black matrix may be referred to as a bezel area.

An area size of the non-display area NAA, that is, the bezel area, is decreasing to provide the largest possible display area AA to a user within a limited size of the display device. In addition, to reduce a width of the bezel area, the area in which the sealing material is disposed may overlap a circuit area in the non-display area NAA. For example, the area in which the sealing material is disposed may overlap an area in which a plurality of link lines are disposed.

In one example, as a demand for a display device having a high resolution increases, a greater number of signal lines are implemented. Accordingly, the number of signal lines and the number of link lines corresponding thereto are also increasing. However, as the number of link lines increases, various problems may occur. For example, while the number of link lines increases, an area size of the bezel area decreases, so that it may be difficult to arrange the plurality of link lines only at the same layer.

Accordingly, to arrange the plurality of link lines in the narrow bezel area, the display device according to an eample embodiment of the present disclosure may include a triple link line structure.

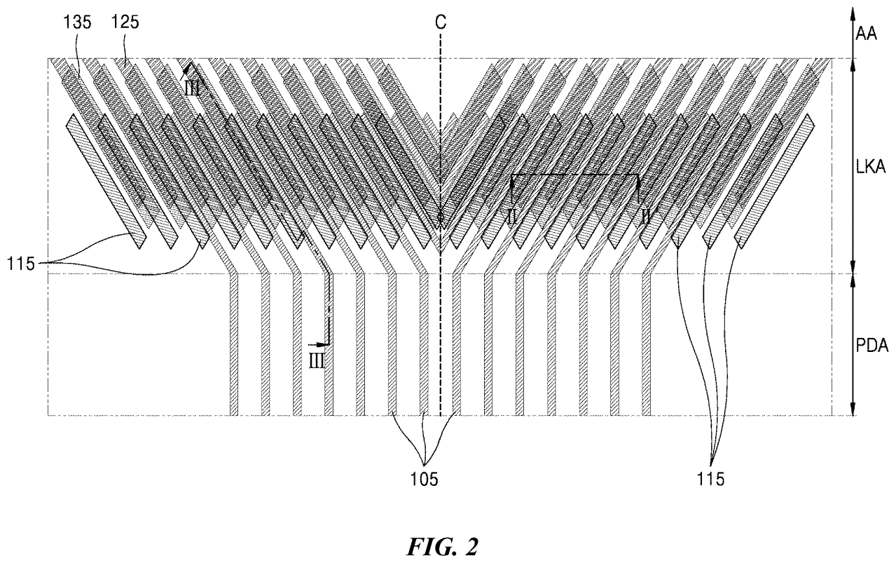

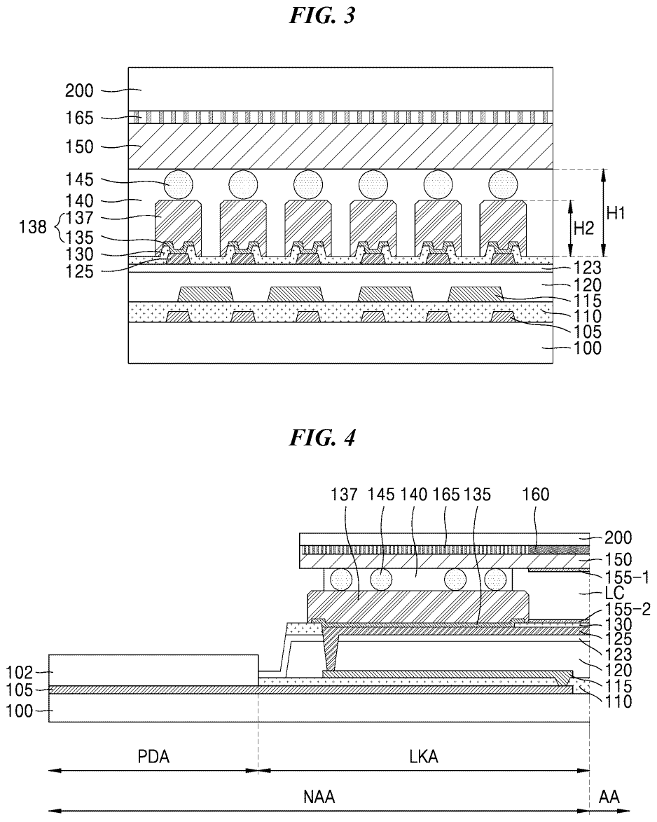

FIGS. 2 to 4 are diagrams illustrating a display device according to an example embodiment of the present disclosure. FIG. 2 is a plan view illustrating a portion of a link area according to an example embodiment of the present disclosure. In FIG. 2, for convenience of description, only a first structure 135 of a protective structure 138 is illustrated. FIG. 3 is a cross-sectional view taken along a line II-II′ in FIG. 2. FIG. 4 is a cross-sectional view taken along a line III-III′ in FIG. 2. For convenience of description, FIGS. 2 to 4 illustrate a partial area of the area in which the sealing material 140 is disposed overlapping the area in which the plurality of link lines are disposed in the non-display area NAA. The area in which the plurality of link lines are disposed may be a link area LKA.

As illustrated in FIGS. 2 to 4, a plurality of link lines 105, 115, and 125 may be arranged at different layers. The plurality of link lines 105, 115, and 125 may include a first link line 105, a second link line 115, and a third link line 125. The first link line 105, the second link line 115, and the third link line 125 may be arranged to be staggered with each other in a vertical direction. In another example, the first link line 105 and the second link line 115 may be arranged to overlap each other at least partially in the vertical direction. In addition, the second link line 115 and the third link line 125 may be arranged to overlap each other at least partially in the vertical direction. The triple link line structure may reduce a width of a gap between the first link line 105, the second link line 115, and the third link line 125 adjacent thereto. Accordingly, in a plan view, area sizes occupied by the first to third link lines 105, 115, and 125 in the bezel area may be reduced to realize a narrow bezel or a zero bezel. The first link line 105, the second link line 115, or the third link line 125 may include a metal material.

As shown in FIG. 2, the first link line 105, the second link line 115, and the third link line 125 may be arranged in the same direction. For example, a first group of the first link line 105, the second link line 115, and the third link line 125 disposed on a left side with respect to a center line C may be disposed in a downward diagonal direction from an upper left end to a lower right end. In addition, a second group of the first link line 105, the second link line 115, and the third link line 125 disposed on a right side with respect to the center line C may be disposed in a downward diagonal direction from an upper right end to a lower left end. The first link line 105 may extend in a linear line shape in a pad area PDA. In addition, the protective structure 138 including the first structure 135 may be disposed to overlap along a shape of the third link line 125.

As shown in FIGS. 3 and 4, the first link line 105, the second link line 115, and the third link line 125 may be disposed at different layers on the first substrate 100 in the link area LKA. Insulating layers may be disposed between the first link line 105, the second link line 115, and the third link line 125. For example, a gate insulating layer 110 may be disposed between the first link line 105 and the second link line 115. The gate insulating layer 110 may be composed of a single layer or multiple layers made of one or more inorganic insulating materials, such as silicon oxide (SiOx) or silicon nitride (SiNx). A first planarization layer 120 and a second planarization layer 123 may be disposed between the second link line 115 and the third link line 125. The first planarization layer 120 and the second planarization layer 123 may include an organic insulating material.

A plurality of protective structures 138, composed of a first structure (or first protective structure) 135 and a second structure (or second protective structure) 137, may be disposed on the plurality of third link lines 125, respectively. The plurality of protective structures 138 may be arranged to correspond to the plurality of third link lines 125, respectively.

A passivation layer 130 may be disposed on an edge of the third link line 125 and on the second planarization layer 123. The passivation layer 130 may be composed of a single layer or multiple layers made of one or more inorganic insulating materials, such as silicon oxide (SiOx) or silicon nitride (SiNx).

The first structure (or first protective structure) 135 may be disposed on a portion of the third link line 125 that is not covered by the passivation layer 130. The first structure 135 may be in direct contact with the third link line 125. The first structure 135 may include a material for preventing or suppressing corrosion of the third link line 125. For example, the first structure 135 may include a metal oxide material as a corrosion-resistant material capable of preventing or suppressing corrosion of a metal material. For example, the first structure 135 may include indium tin oxide (ITO) or indium zinc oxide (IZO).

The second structure (or second protective structure) 137 may be disposed on the first structure 135. The second structure 137 may have a width greater than that of the first structure 135. Accordingly, the second structure 137 may cover all of a top surface and side surface of the first structure 135 and extend to a partial area of the passivation layer 130. The second structure 137 may have a pillar shape protruding from a surface of the passivation layer 130 toward a second substrate 200. The second structure 137 may include an organic insulating material. For example, the second structure 137 may be made of photo acryl (PAC) or polyimide (PI).

The third link line 125 may be disposed on the second planarization layer 123 including the organic insulating material and may be covered with the passivation layer 130 so as to be protected. Accordingly, a step may occur between a portion where the third link line 125 is disposed and a portion where the third link line 125 is not disposed.

When a sealing process of applying the sealing material 140 is performed in a state in which a front surface (or top surface) of the third link line 125 is covered by the passivation layer 130, a structure having a relatively great size is typically included in the sealing material 140 to maintain a separation space between the first substrate 100 and the second substrate 200. The structure may include a material having rigidity to maintain the separation space.

When the sealing material 140 including the structure is applied between the first substrate 100 and the second substrate 200 and a pressure is applied for bonding, the structure having the rigidity may increase stress on the passivation layer 130. Thus, cracks may occur on a surface of the passivation layer 130. When moisture penetrates through the cracks, the third link line 125 under the passivation layer 130 may come into contact with moisture.

When a voltage is applied in the state in which the third link line 125 is in contact with moisture permeated thereinto, corrosion may occur in the third link line 125 including a conductive material (or a metal material) due to an electric field and moisture. When the corrosion occurs in the third link line 125, a defect may occur in an operation of the display device, and reliability of a product may be deteriorated.

In addition, when the pressure applied from the structure having the rigidity included in the sealing material 140 is strong, the third link line 125 may be damaged.

To solve such a problem, in an example embodiment of the present disclosure, the protective structure 138 including the first structure 135 and the second structure 137 may be disposed on the third link line 125 to prevent or protect the third link line 125 from being damaged by the moisture penetration. Also, by constructing the second structure 137 in the pillar shape protruding toward the second substrate 200, a height capable of maintaining the separation space between the first substrate 100 and the second substrate 200 may be secured. In addition, a size of a gap filler 145 may be reduced by introducing the sealing material 140 including the gap filler 145. Furthermore, as the protective structure 138 is disposed between the gap filler 145 and the third link line 125, the third link line 125 may be prevented or protected from being damaged by the stress, such as a pressure applied by the gap filler 145.

In addition, by disposing the protective structure 138 at a position where the third link line 125 is disposed, the separation space may be uniformly maintained.

The second link line 115 and the first link line 105 may be disposed under the third link line 125. In an example embodiment, as illustrated in FIG. 4, the third link line 125 may be electrically connected to the second link line 115 via a connection electrode extending through the second planarization layer 123 and the first planarization layer 120. In addition, the second link line 115 may be electrically connected to the first link line 105 via another connection electrode extending through the gate insulating layer 110. The first link line 105 may extend from the link area LKA to the pad area PDA electrically connected to the flexible circuit board 102.

A lower alignment film 155-2 may be disposed on the passivation layer 130 of the first substrate 100 so as not to overlap the sealing material 140. In addition, an upper alignment film 155-1 may be disposed beneath an overcoat layer 150 of the second substrate 200. A liquid crystal layer LC may be filled between the upper alignment film 155-1 and the lower alignment film 155-2. A black matrix 160 may be disposed between the overcoat layer 150, on which the upper alignment film 155-1 is disposed, and the second substrate 200 such that various metal lines are not visible to the user. A decoration layer 165 surrounding the bezel area may be disposed between the second substrate 200 and the overcoat layer 150 corresponding to the portion where the sealing material 140 is disposed, but the present disclosure may not be limited thereto. For example, the black matrix may be disposed at a position where the decoration layer 165 is disposed.

The sealing material 140 may be disposed between the second substrate 200 and the first substrate 100. The gap filler 145, which may be a shock-absorbing structure, may be disposed between the protective structure 138 and the second substrate 200. The gap filler 145 may be disposed at a position corresponding to the position where the protective structure 138 is disposed. The sealing material 140 may include an organic material having adhesiveness, such as silicone, polyurethane, epoxy, or acryl. The gap filler 145 may include silica particles, glass fibers, or ceramic particles, but may not be limited thereto. In an example embodiment, the gap filler 145 may have a spherical shape.

An overall height H2 of the protective structure 138 may be greater than ½ of an overall height H1 of the sealing material 140 disposed between the first substrate 100 and the second substrates 200. Accordingly, because a size of the gap filler 145 disposed between the protective structure 138 and the second substrate 200 may be reduced, a manufacturing cost may be reduced.

When the sealing material 140 is applied to bond the first substrate 100 and the second substrate 200 to each other and the bonding is performed, the pressure may be reduced at a point where the gap filler 145 is in contact with the protective structure 138. Accordingly, it may lead to a robust structure capable of relieving the stress applied to the link line (e.g., the third link line 125) when the first substrate 100 and the second substrate 200 are bonded together. In addition, as the gap filler 145 and the protective structure 138 are arranged to overlap each other in the vertical direction, the separation space between the first substrate 100 and the second substrate 200 may be maintained.

As illustrated in FIG. 4, the plurality of gap fillers 145 may be arranged on the second structure 137 of the protective structure 138 having a bar shape to be spaced apart from each other. As the plurality of gap fillers 145 are disposed on one protective structure 138 to be in contact therewith via the bonding, a pressure applied to the protective structure 138 may be dispersed. Accordingly, because an increase in strain caused by the stress applied to the third link line 125 disposed under the protective structure 138 may be prevented or suppressed, the cracks may be prevented or suppressed from occurring.

Because the cracks may be prevented or suppressed from occurring in the third link line 125, moisture may be blocked from penetrating via the cracks and coming into contact with the third link line 125. Accordingly, the potential corrosion of the third link line 125 due to the moisture contact may be prevented or suppressed, thereby preventing or suppressing the resulting defect from occurring in the display device. Accordingly, a defect rate of the display device resulting from the corrosion of the link lines of the display device may be reduced, and the production yield may increase. Thus, production energy required for additional production of the display device may be reduced, which may result in the beneficial effect of reducing emission of greenhouse gas.

In addition, by applying the triple link line structure including the first link line, the second link line, and the third link line disposed at the different layers, multiple link lines may be disposed in the limited bezel area. Accordingly, a resolution of a liquid crystal display may be increased.

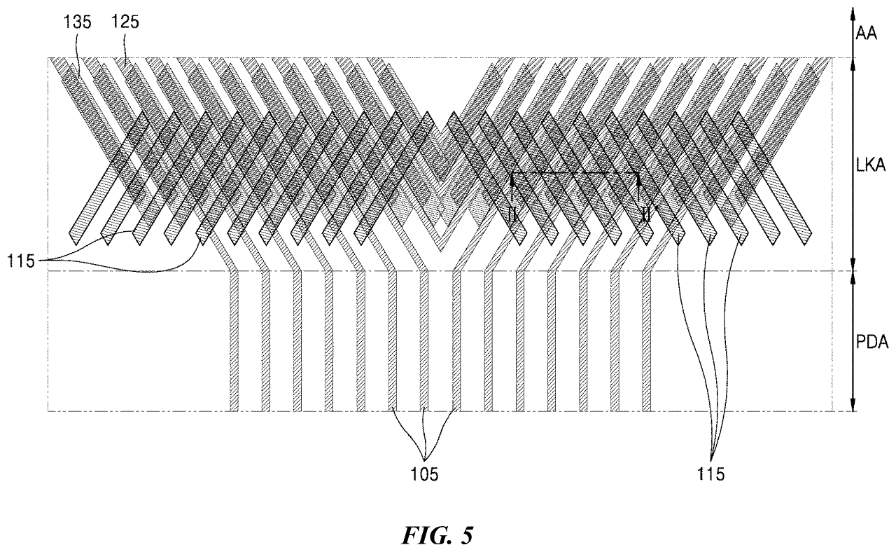

FIG. 5 is a plan view illustrating a portion of a link area according to another example embodiment of the present disclosure.

FIG. 5 may include the same configuration as that in FIG. 2 except for a direction in which the second link line 115 is disposed. For example, the first link line 105 and the third link line 125 disposed on the left side may be disposed in the downward diagonal direction from the upper left end to the lower right end. The second link line 115 disposed on the left side may be disposed in an upward diagonal direction from the lower left end to the upper right end. In addition, the first link line 105 and the third link line 125 disposed on the right side may be disposed in the downward diagonal direction from the upper right end to the lower left end. The second link line 115 disposed on the right side may be disposed in an upward diagonal direction from the lower right end to the upper left end. In addition, the protective structure 138 including the first structure 135 may be disposed to overlap along the shape of the third link line 125.

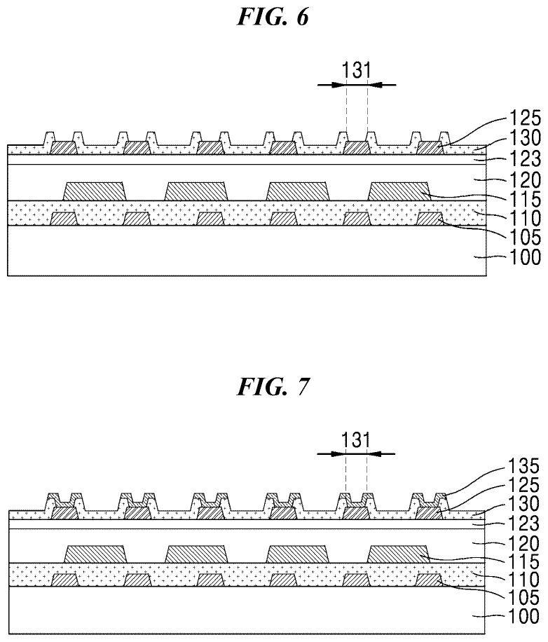

FIGS. 6 to 9 are diagrams illustrating a method for manufacturing a display device according to another example embodiment of the present disclosure.

As shown in FIG. 6, a plurality of first link lines 105 may be disposed on the first substrate 100. The first substrate 100 may include glass but is not limited thereto. The first link lines 105 adjacent to each other may be arranged to be spaced apart from each other with a separation space defined therebetween. The first link lines 105 may include the same conductive material (or a metal material) as that of the gate electrode. The plurality of first link lines 105 may be electrically connected to gate lines, respectively. The gate insulating layer 110 covering the first link line 105 may be disposed. The gate insulating layer 110 may include an inorganic insulating material.

A plurality of second link lines 115 may be disposed on the gate insulating layer 110. The plurality of second link lines 115 may be disposed at a different layer from the plurality of first link lines 105. The second link line 115 may be disposed such that at least a partial area thereof overlaps the first link line 105 in the vertical direction. The plurality of second link lines 115 may include the same conductive material (or a metal material) as that of a source electrode or a drain electrode. The plurality of second link lines 115 may be electrically connected to data lines, respectively. The first planarization layer 120 covering the second link line 115 may be disposed. The first planarization layer 120 may be formed to have a sufficient thickness to flatten a step or steps resulting from a lower circuit element and may include an organic insulating material.

The second planarization layer 123 may be disposed on the first planarization layer 120. The second planarization layer 123 may include an inorganic insulating material. For example, the second planarization layer 123 may be composed of a single layer or multiple layers made of one or more inorganic insulating materials, such as silicon oxide (SiOx) or silicon nitride (SiNx).

A plurality of third link lines 125 may be disposed on the second planarization layer 123. The third link lines 125 adjacent to each other may be arranged to be spaced apart from each other with a separation space defined therebetween. The plurality of third link lines 125 may be disposed at a different layer from the plurality of second link lines 115. The third link line 125 may be disposed such that at least a partial area thereof overlaps the second link line 115 in the vertical direction. The plurality of third link lines 125 may include the same conductive material (or a metal material) as that of a common electrode.

The passivation layer 130 may be disposed on the third link line 125. The passivation layer 130 may include an inorganic insulating material. For example, the passivation layer 130 may be composed of a single layer or multiple layers made of one or more inorganic insulating materials, such as silicon oxide (SiOx) or silicon nitride (SiNx).

Subsequently, one or more openings 131 may be defined in the passivation layer 130. The opening 131 may be defined by removing a partial area of the passivation layer 130. The opening 131 may correspond to an area in which the third link line 125 is disposed. For example, the opening 131 may expose a portion of a surface of the third link line 125. The passivation layer 130 may cover an upper edge of the third link line 125.

As illustrated in FIG. 7, the first structure (or first protective structure) 135 may be disposed on partial areas of the third link line 125 and the passivation layer 130. The first structure 135 may be disposed to overlap the opening 131. Accordingly, the first structure 135 may be in direct contact with the exposed surface of the third link line 125. In an example embodiment, the first structure 135 may extend to a partial area of the passivation layer 130 while being in contact with the third link line 125. When viewed in a plan view, the first structure 135 may overlap the third link line 125 in the vertical direction. For example, when viewed in a plan view, the first structure 135 may overlap the third link line 125 in a bar shape.

The first structure 135 may include a material for preventing corrosion of the third link line 125. For example, the first structure 135 may include a metal oxide material for preventing corrosion of the third link line 125. For example, the metal oxide material may include indium tin oxide (ITO) or indium zinc oxide (IZO). The first structure 135 may be made of the same material as and formed in the same process as a pixel electrode connected to the drain electrode in the display area AA.

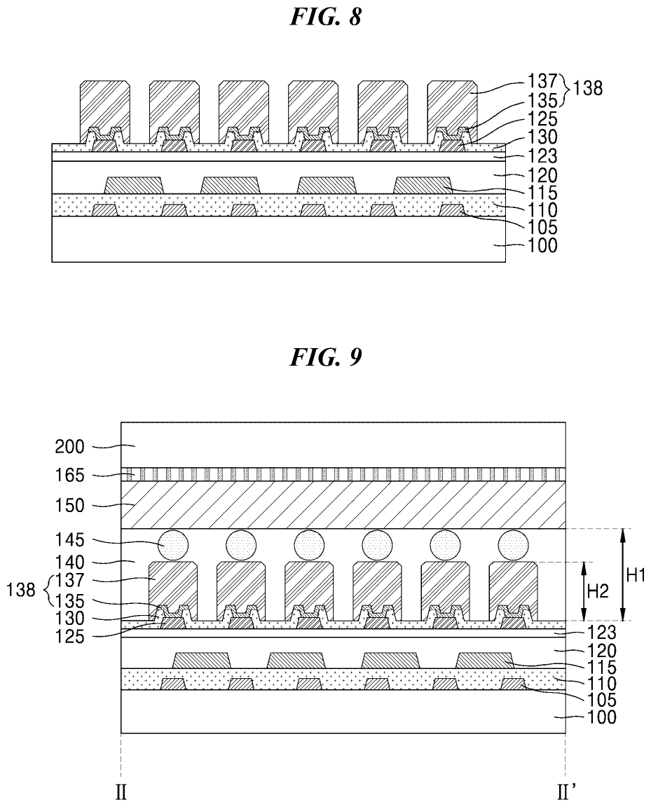

As shown in FIG. 8, the second structure (or second protective structure) 137 may be formed on the first structure 135. The second structure 137 may cover a partial area of the passivation layer 130 while also covering the first structure 135. Accordingly, the third link line 125 may be protected from potential cracks by the protective structure 138 including the first structure 135 and the second structure 137.

The second structure 137 may have a pillar shape protruding from the passivation layer 130 in a cross-sectional view. The second structure 137 may be made of the same material and formed in the same process as a column spacer disposed in the display area AA. The second structure 137 may be a structure for maintaining a constant cell gap between the first substrate 100 and the second substrate 200. When viewed in a plan view, the second structure 137 may overlap the first structure 135 in the vertical direction. For example, when viewed in a plan view, the second structure 137 may overlap the third link line 125 and the first structure 135 in a bar shape.

The second structure 137 may include an organic insulating material to adjust a height and a shape thereof. It may be difficult for the inorganic insulating material to realize the height and the shape to be implemented by the second structure 137. For example, the second structure 137 may be made of photo acryl (PAC), polyimide (PI), or the like, but may not be limited thereto.

As shown in FIG. 9, the second substrate 200 is disposed at a position facing the first substrate 100. In an area corresponding to the display area AA of the second substrate 200, a color filter layer corresponding to the plurality of pixels may be disposed (not illustrated). The second substrate 200 may include the overcoat layer 150. The decoration layer 165 surrounding the bezel area may be disposed between the second substrate 200 and the overcoat layer 150, but the present disclosure may not be limited thereto. For example, the black matrix may instead be disposed at a position where the decoration layer 165 is illustrated as disposed.

The first substrate 100 and the second substrate 200 may be bonded to each other by the sealing material 140 including the gap filler 145. For example, the sealing material 140 may include an organic material having adhesiveness, such as silicone, polyurethane, epoxy, or acryl. The gap filler 145 may include silica particles, glass fibers, or ceramic particles, but may not be limited thereto.

The gap filler 145 may help maintain a separation space (a gap) between the first substrate 100 and the second substrate 200 when applying a pressure to bond the first substrate 100 and the second substrate 200 to each other. The gap filler 145 may be disposed between the second structure 137 of the protective structure 138 and the overcoat layer 150. Accordingly, a size of the gap filler 145 may be adjusted based on a vertical dimension between the second structure 137 and the overcoat layer 150. Accordingly, the gap filler 145 having a relatively smaller size than the gap filler typically disposed between the first substrate 100 and the second substrate 200 may be used, thereby reducing the manufacturing cost.

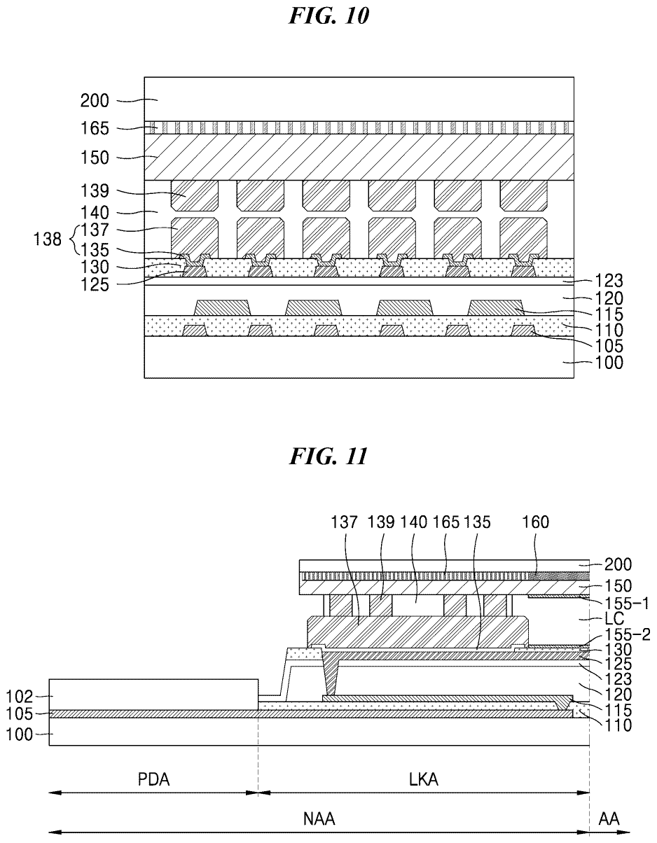

FIGS. 10 and 11 are diagrams illustrating a display device according to still another example embodiment of the present disclosure. In FIGS. 10 and 11, the same components as those in FIGS. 3 and 4 may be assigned with the same reference numerals. Accordingly, redundant descriptions will be omitted or briefly made, and parts that are different will be described.

As illustrated in FIGS. 10 and 11, the plurality of protective structures 138 composed of the first structure (or first protective structure) 135 and the second structure (or second protective structure) 137 protecting the plurality of third link lines 125 may be disposed in the link area LKA on the first substrate 100. The plurality of protective structures 138 may be arranged to correspond to the plurality of third link lines 125, respectively.

The second link line 115 and the first link line 105 may be disposed at different layers under the third link line 125. In an example embodiment, the third link line 125 may be electrically connected to the second link line 115 via the connection electrode extending through the second planarization layer 123 and the first planarization layer 120. In addition, the second link line 115 may be electrically connected to the first link line 105 via another connection electrode extending through the gate insulating layer 110. The first link line 105 may extend from the link area LKA to the pad area PDA electrically connected to the flexible circuit board 102.

The lower alignment film 155-2 may be disposed on the passivation layer 130 of the first substrate 100 so as not to overlap the sealing material 140. In addition, the upper alignment film 155-1 may be disposed beneath the overcoat layer 150 of the second substrate 200. The liquid crystal layer LC may be filled between the upper alignment film 155-1 and the lower alignment film 155-2. The black matrix 160 may be disposed between the overcoat layer 150, on which the upper alignment film 155-1 is disposed, and the second substrate 200 such that the various metal lines are not visible to the user. The decoration layer 165 surrounding the bezel area may be disposed between the second substrate 200 and the overcoat layer 150 corresponding to the portion where the sealing material 140 is disposed, but the present disclosure may not be limited thereto. For example, the black matrix may instead be disposed at the position where the decoration layer 165 is illustrated as being disposed.

A plurality of auxiliary structures 139 may be disposed on the second substrate 200. The auxiliary structures 139 may be formed on the overcoat layer 150 of the second substrate 200 so as to be aligned with the position where the protective structure 138 is disposed. For example, the auxiliary structure 139 may have a shape that faces one surface of the protective structure 138 and protrudes from the overcoat layer 150 of the second substrate 200. For example, the auxiliary structure 139 may include the same material as the second structure 137. For example, the auxiliary structure 139 may be made of an organic insulating material including photo acryl (PAC) or polyimide (PI). However, the material is not limited thereto. An overall thickness of the protective structure 138 may be equal to or greater than an overall thickness of the auxiliary structure 139.

The plurality of auxiliary structures 139 may be arranged such that one surface of the auxiliary structure 139 faces one surface of the protective structure 138. Accordingly, when the sealing material 140 is applied to bond the first substrate 100 and the second substrate 200 to each other and the bonding is performed, a pressure may be reduced at a point where the auxiliary structure 139 is in contact with the protective structure 138. In addition, as the auxiliary structure 139 and the protective structure 138 are disposed to overlap each other in the vertical direction, the separation space between the first substrate 100 and the second substrate 200 may be maintained. Accordingly, because the gap filler (e.g., gap filler 145) in the sealing material 140 may be removed, the manufacturing cost may be reduced.

As illustrated in FIG. 11, the plurality of auxiliary structures 139 may be arranged to be spaced apart from each other on the protective structure 138 having the bar shape. As a plurality of auxiliary structures 139 are disposed on one protective structure 138 to be in contact therewith by the bonding, the pressure applied to the protective structure 138 may be dispersed. Accordingly, because an increase in strain caused by the stress applied to the third link line 125 disposed under the protective structure 138 may be prevented or suppressed, the cracks may be prevented or suppressed from occurring.

A display device according to various example embodiments of the present disclosure may be described as follows.

A display device according to an embodiment of the present disclosure includes a first substrate including a display area and a non-display area surrounding the display area, a second substrate facing the first substrate, a plurality of link lines disposed in the non-display area of the first substrate, the plurality of link lines being disposed at different distances from the second substrate, a plurality of protective structures respectively on link lines closest to the second substrate, among the plurality of link lines, a plurality of shock-absorbing structures between the second substrate and the plurality of protective structures, respectively, and a sealing material surrounding the plurality of shock-absorbing structures in the non-display area between the first substrate and the second substrate.

According to various embodiments of the present disclosure, the plurality of link lines may include first link lines on the first substrate, second link lines above the first link lines, and third link lines above the second link lines, wherein the third link lines are the closest to the second substrate, among the plurality of link lines, and wherein each of the plurality of protective structures is on a corresponding third link line, among the third link lines.

According to various embodiments of the present disclosure, each of the plurality of protective structures may include a first protective structure in direct contact with the corresponding third link line, and a second protective structure on the first protective structure.

According to various embodiments of the present disclosure, the second protective structure hay have a greater width than the first protective structure.

According to various embodiments of the present disclosure, the third link lines may include a conductive metal material, the first protective structure may include a metal oxide material, and the second protective structure may include an organic insulating material.

According to various embodiments of the present disclosure, the display device may further include a passivation layer on the third link lines, the passivation layer having an opening exposing a top surface of the corresponding third link line. The first protective structure may contact the top surface of the corresponding third link line. The second protective structure may entirely cover an upper surface and side surfaces of the first protective structure and may cover a portion of the passivation layer.

According to various embodiments of the present disclosure, the second protective structure may have a pillar shape protruding from the passivation layer toward the second substrate.

According to various embodiments of the present disclosure, in a plan view: the first, second, and third link lines may include a first group of the first, second, and third link lines disposed in a left side of the non-display area and a second group of the first, second, and third link lines disposed in a right side of the non-display area; each first link line, each second link line, and each third link line in the first group may extend in a diagonal direction between an upper left end and a lower right end of the left side of the non-display area; and each first link line, each second link line, and each third link line in the second group extend in a diagonal direction between an upper right end and a lower left end of the right side of the non-display area.

According to various embodiments of the present disclosure, in a plan view: the first, second, and third link lines may include a first group of the first, second, and third link lines disposed in a left side of the non-display area and a second group of the first, second, and third link lines disposed in a right side of the non-display area; each first link line and each third link line in the first group may extend in a diagonal direction between an upper left end and a lower right end of the left side of the non-display area, and each second link line in the first group may extend in a diagonal direction between a lower left end and an upper right end of the left side of the non-display area; and each first link line and each third link line in the second group may extend in a diagonal direction between an upper right end and a lower left end of the right side of the non-display area, and each second link line in the second group may extend in a diagonal direction between a lower right end and an upper left end of the right side of the non-display area.

According to various embodiments of the present disclosure, the display device may further include a gate electrode, a source electrode, a drain electrode, and a common electrode in the display area of the first substrate; a first insulating layer between the first link lines and the second link lines; and a second insulating layer between the second link lines and the third link lines. The first link lines may include a same material as the gate electrode, the second link lines may include a same material as the source electrode or the drain electrode, and the third link lines may include a same material as the common electrode.

According to various embodiments of the present disclosure, each of the plurality of shock-absorbing structures may include a gap filler or an auxiliary structure, the gap filler may include silica particles, glass fibers, or ceramic particles, and the auxiliary structure may protrude from the second substrate to face a corresponding one of the plurality of protective structures and may include an organic insulating material.

In another aspect, a display device according to an example embodiment of the present disclosure may include a first substrate including a display area and a non-display area surrounding the display area, a second substrate overlapping the first substrate, a plurality of link lines in the non-display area of the first substrate, the plurality of link lines being disposed respectively at different distances from the second substrate, a protective structure on a link line closest to the second substrate among the plurality of link lines, and at least one shock-absorbing structure between the protective structure and the second substrate.

According to various embodiments of the present disclosure, the plurality of link lines may include a first link line on the first substrate, a second link line above the first link line, and a third link line above the second link line, wherein the third link line may be the closest to the second substrate, among the plurality of link lines, and the protective structure may be on the third link line.

According to various embodiments of the present disclosure, the protective structure may include a first protective structure in direct contact with the third link line, and a second protective structure covering the first protective structure.

According to various embodiments of the present disclosure, the third link line may include a conductive metal material, the first protective structure may include a metal oxide material, and the second protective structure may include an organic insulating material.

According to various embodiments of the present disclosure, the display device may further include a passivation layer on the third link line and having an opening exposing a top surface of the third link line, wherein the first protective structure may contact the top surface of the third link line. The second protective structure may have a greater width than the first protective structure, may cover an upper surface and side surfaces of the first protective structure entirely, and may cover a portion of the passivation layer.

According to various embodiments of the present disclosure, the second protective structure may have a pillar shape protruding from the passivation layer toward the second substrate.

According to various embodiments of the present disclosure, the display device may further include a gate electrode, a source electrode, a drain electrode, and a common electrode in the display area of the first substrate, a first insulating layer between the first link line and the second link line, and a second insulating layer between the second link line and the third link line. The first link line may include a same material as the gate electrode, the second link line may include a same material as the source electrode or the drain electrode, and the third link line may include a same material as the common electrode.

According to various embodiments of the present disclosure, the display device may further include a first insulating layer between the first link line and the second link line, and a second insulating layer between the second link line and the third link line. The second link line may be electrically connected with the first link line via a first contact hole through the first insulating layer, and the third link line may be electrically connected with the second link line via a second contact hole through the second insulating layer.

According to various embodiments of the present disclosure, the display device may further include a sealing material surrounding the at least one shock-absorbing structure in the non-display area between the first substrate and the second substrate, wherein the at least one shock-absorbing structure may include a plurality of spherical shaped gap fillers or a plurality of pillar-shaped auxiliary structures.

Although some example embodiments of the present disclosure have been described above with reference to the accompanying drawings, the present disclosure may not be limited to these example embodiments and may be implemented in various different forms. Those of ordinary skill in the technical field to which the present disclosure belongs will be able to appreciate that the present disclosure may be implemented in other specific forms without departing from the technical idea, spirit, or features of the present disclosure. Therefore, it should be understood that the example embodiments as described above are not restrictive but are illustrative in all respects.

What is claimed is:

1. A display device, comprising:
a first substrate including a display area and a non-display area surrounding the display area;
a second substrate facing the first substrate;
a plurality of link lines disposed in the non-display area of the first substrate, the plurality of link lines being disposed at different distances from the second substrate;
a plurality of protective structures respectively on link lines closest to the second substrate, among the plurality of link lines;
a plurality of shock-absorbing structures between the second substrate and the plurality of protective structures, respectively; and
a sealing material surrounding the plurality of shock-absorbing structures in the non-display area between the first substrate and the second substrate.

2. The display device of claim 1, wherein the plurality of link lines include:
first link lines on the first substrate;
second link lines above the first link lines; and
third link lines above the second link lines,
wherein the third link lines are the closest to the second substrate, among the plurality of link lines, and
wherein each of the plurality of protective structures is on a corresponding third link line, among the third link lines.

3. The display device of claim 2, wherein each of the plurality of protective structures includes:
a first protective structure in direct contact with the corresponding third link line; and
a second protective structure on the first protective structure.

4. The display device of claim 3, wherein the second protective structure has a greater width than the first protective structure.

5. The display device of claim 3, wherein the third link lines include a conductive metal material, the first protective structure includes a metal oxide material, and the second protective structure includes an organic insulating material.

6. The display device of claim 3, further comprising a passivation layer on the third link lines, the passivation layer having an opening exposing a top surface of the corresponding third link line,
wherein the first protective structure contacts the top surface of the corresponding third link line, and
wherein the second protective structure entirely covers an upper surface and side surfaces of the first protective structure and covers a portion of the passivation layer.

7. The display device of claim 6, wherein the second protective structure has a pillar shape protruding from the passivation layer toward the second substrate.

8. The display device of claim 2, wherein, in a plan view:
the first, second, and third link lines include a first group of the first, second, and third link lines disposed in a left side of the non-display area and a second group of the first, second, and third link lines disposed in a right side of the non-display area;
each first link line, each second link line, and each third link line in the first group extend in a diagonal direction between an upper left end and a lower right end of the left side of the non-display area; and
each first link line, each second link line, and each third link line in the second group extend in a diagonal direction between an upper right end and a lower left end of the right side of the non-display area.

9. The display device of claim 2, wherein, in a plan view:
the first, second, and third link lines include a first group of the first, second, and third link lines disposed in a left side of the non-display area and a second group of the first, second, and third link lines disposed in a right side of the non-display area;
each first link line and each third link line in the first group extend in a diagonal direction between an upper left end and a lower right end of the left side of the non-display area, and each second link line in the first group extends in a diagonal direction between a lower left end and an upper right end of the left side of the non-display area; and
each first link line and each third link line in the second group extend in a diagonal direction between an upper right end and a lower left end of the right side of the non-display area, and each second link line in the second group extends in a diagonal direction between a lower right end and an upper left end of the right side of the non-display area.

10. The display device of claim 2, further comprising:
a gate electrode, a source electrode, a drain electrode, and a common electrode in the display area of the first substrate;
a first insulating layer between the first link lines and the second link lines; and
a second insulating layer between the second link lines and the third link lines,
wherein the first link lines include a same material as the gate electrode,
wherein the second link lines include a same material as the source electrode or the drain electrode, and
wherein the third link lines include a same material as the common electrode.

11. The display device of claim 1, wherein:
each of the plurality of shock-absorbing structures includes a gap filler or an auxiliary structure;
the gap filler includes silica particles, glass fibers, or ceramic particles; and
the auxiliary structure protrudes from the second substrate to face a corresponding one of the plurality of protective structures and includes an organic insulating material.

12. A display device, comprising:
a first substrate including a display area and a non-display area surrounding the display area;
a second substrate overlapping the first substrate;
a plurality of link lines in the non-display area of the first substrate, the plurality of link lines being disposed respectively at different distances from the second substrate;
a protective structure on a link line closest to the second substrate among the plurality of link lines; and
at least one shock-absorbing structure between the protective structure and the second substrate.

13. The display device of claim 12, wherein the plurality of link lines include:
a first link line on the first substrate;
a second link line above the first link line; and
a third link line above the second link line,
wherein the third link line is the closest to the second substrate, among the plurality of link lines, and the protective structure is on the third link line.

14. The display device of claim 13, wherein the protective structure includes:
a first protective structure in direct contact with the third link line; and
a second protective structure covering the first protective structure.

15. The display device of claim 14, wherein the third link line includes a conductive metal material, the first protective structure includes a metal oxide material, and the second protective structure includes an organic insulating material.

16. The display device of claim 14, further comprising:
a passivation layer on the third link line and having an opening exposing a top surface of the third link line,
wherein the first protective structure contacts the top surface of the third link line, and
wherein the second protective structure has a greater width than the first protective structure, the second protective structure covering an upper surface and side surfaces of the first protective structure entirely and covering a portion of the passivation layer.

17. The display device of claim 16, wherein the second protective structure has a pillar shape protruding from the passivation layer toward the second substrate.

18. The display device of claim 13, further comprising:
a gate electrode, a source electrode, a drain electrode, and a common electrode in the display area of the first substrate;
a first insulating layer between the first link line and the second link line; and
a second insulating layer between the second link line and the third link line,
wherein the first link line includes a same material as the gate electrode,
wherein the second link line includes a same material as the source electrode or the drain electrode, and
wherein the third link line includes a same material as the common electrode.

19. The display device of claim 13, further comprising:
a first insulating layer between the first link line and the second link line; and
a second insulating layer between the second link line and the third link line,
wherein the second link line is electrically connected with the first link line via a first contact hole through the first insulating layer, and
wherein the third link line is electrically connected with the second link line via a second contact hole through the second insulating layer.

20. The display device of claim 12, further comprising:
a sealing material surrounding the at least one shock-absorbing structure in the non-display area between the first substrate and the second substrate,
wherein the at least one shock-absorbing structure includes a plurality of spherical shaped gap fillers or a plurality of pillar-shaped auxiliary structures.
